(19) United States
(12) Patent Application Publication
(10) Pub. No.: US 2014/0070225 A1
(43) Pub. Date: Mar. 13, 2014

(54) Hydrogenation and Crystallization of Polycrystalline Silicon

(71) Applicant: Apple Inc., Cupertino, CA (US)

(72) Inventors: Cheng-Ho Yu, Cupertino, CA (US); Marduke Yousefpor, San Jose, CA (US); Yu-Cheng Chen, Cupertino, CA (US); Stephen S. Poon, San Jose, CA (US); Ting-Kuo Chang, Cupertino, CA (US); Young Bae Park, Cupertino, CA (US)

(73) Assignee: Apple Inc., Cupertino, CA (US)

(21) Appl. No.: 14/020,620

(22) Filed: Sep. 6, 2013

Related U.S. Application Data
(60) Provisional application No. 61/698,455, filed on Sep. 7, 2012.

(51) Int. Cl. H01L 29/786; H01L 29/66

(52) U.S. Cl. CPC H01L 29/78675; H01L 29/66757
USPC 257/72; 438/158

(57) ABSTRACT

A TFT stack for a liquid crystal display is provided. The TFT stack includes a silicon layer that includes a heavily doped region, a non-doped region, and a lightly doped region between the heavily doped region and the non-doped region. The heavily doped region is hydrogenated. The TFT stack also includes an insulation layer that includes a first portion formed over the lightly doped region and a second portion disposed over the non-doped region and a gate metal electrode layer formed over the second portion of the non-doped region. The TFT stack also includes a first dielectric layer disposed over the gate metal electrode and over the first portion of the insulation layer. The heavily doped region is hydrogenated to reduce the dependence of the capacitance between the gate metal electrode and the conductive layer C_{gd} upon a bias voltage being applied between the gate metal electrode and the conductive layer.

### CROSS-REFERENCE TO RELATED APPLICATION

This application claims priority under 35 U.S.C. §119(e) to U.S. Provisional Patent Application No. 61/698,455, filed Sep. 7, 2012, and entitled “Hydrogenation and Crystallization of Polycrystalline Silicon,” the entirety of which is incorporated by reference as if fully cited herein.

### TECHNICAL FIELD

The present invention generally relates to thin film transistors (TFT) for a liquid crystal display. More specifically, the invention relates to hydrogenation and crystallization of polycrystalline silicon for reducing display noises.

### BACKGROUND

Liquid crystal displays (LCDs) generally display images by transmitting or blocking light through the action of liquid crystals. LCDs have been used in a variety of computing displays and devices, including notebook computers, desktop computers, tablet computing devices, mobile phones (including smart phones) automobile in-cabin displays, on appliances, as televisions, and so on. LCDs often use an active matrix to drive liquid crystals in a pixel region. In some LCDs, a thin-film transistor (TFT) is used as a switching element in the active matrix.

FIG. 1 illustrates a perspective view of a sample electronic device, such as a tablet computer. The electronic device includes a touch screen display 100 enclosed by a housing 138. The touch screen display 100 incorporates a touch panel 102 and an LCD, although alternative embodiments may employ an OLED layer instead of an LCD. The LCD is not shown in FIG. 1. Although a tablet computing device is illustrated in FIG. 1, it should be appreciated that the discussion herein may be equally applicable to any display and/or electronic device incorporating a display, such as a smart phone, notebook or laptop computer, all-in-one computing device, personal digital assistant, multimedia player, e-book reader, and so on.

FIG. 2 illustrates a simplified cross-sectional view of a sample tablet computing device shown in FIG. 1 (the cross-section is shown by arrows 2-2 in FIG. 1). LCD 204 includes an array of pixels and an array of TFTs associated with the pixels. The LCD 204 may be a display with an integrated touch sensing module or subsystem.

The LCD 204 may suffer from display noise, which may cross-couple to a capacitive touch sensing subsystem of the tablet computing device or other electronic device. Essentially, the capacitance between the gate and drain of a TFT for a given pixel may vary with a voltage between a gate and a drain, which interferes with the touch sensing subsystem, and thus acts as a parasitic capacitance on that subsystem. Thus, the display noise may interfere with detection of touches or other capacitive sense events during operation. The display noise in the LCD 204 may be sensitive to a finger touching the touch panel 102. The impact of finger touches may vary with the user and/or environment in which the device is used. For example, a human finger may be relatively cold or warm. The device 100 may be used in a hot and humid environment, or a cold and dry environment, all of which may change the sensitivity of the LCD to display noise.

### SUMMARY

Embodiments described herein may provide a thin-film transistor (TFT) for a liquid crystal display (LCD). The LCD may include certain structural elements that may reduce or minimize display noise. The TFT includes a polycrystalline silicon layer that has a non-doped region, a lightly doped drain (LDD) region, and a heavily doped region denoted by N+. The TFT also includes a gate electrode, a drain electrode, and a source electrode. In one embodiment, the heavily doped region connected to the drain electrode is hydrogenated to reduce the variation of the capacitance C_{gd} between the gate electrode and the drain electrode upon a bias voltage applied between the gate electrode and the drain electrode. In another embodiment, the polycrystalline silicon includes a majority of small crystals having orientation in <100>. Embodiments also provide methods for forming the TFTs to reduce display noises.

In one embodiment, a TFT stack for a liquid crystal display is provided. The TFT stack includes a silicon layer that includes a heavily doped region, a non-doped region, and a lightly doped region between the heavily doped region and the non-doped region. The heavily doped region is hydrogenated. The TFT stack also includes an insulation layer that includes a first portion formed over the lightly doped region and a second portion disposed over the non-doped region. The TFT stack further includes a gate metal electrode layer formed over the second portion of the non-doped region. The TFT stack also includes a first dielectric layer disposed over the gate metal electrode and over the first portion of the insulation layer. The first dielectric layer is formed through a chemical vapor deposition (CVD) process at a first temperature. A via is formed above the heavily doped region. The TFT stack further includes a conductive layer over the via to contact the heavily doped region. The heavily doped region is hydrogenated to reduce the dependence of the capacitance between the gate metal electrode and the conductive layer C_{gd} upon a bias voltage being applied between the gate metal electrode and the conductive layer.

In another embodiment, a method is provided for fabricating a TFT stack. The method includes depositing a silicon layer on a substrate. The silicon layer includes a heavily doped region, a non-doped region, and a lightly doped region between the heavily doped region and the non-doped region. The method also includes forming an insulation layer having a first portion over the lightly doped region and a second portion over the non-doped region, and forming a gate metal electrode over the second portion of the insulation layer above the non-doped region of the silicon layer. The method further includes depositing a first dielectric layer over the gate metal electrode by using a mixture of precursors including hydrogen containing precursors during a chemical vapor deposition (CVD), over the first portion of the insulator layer above the lightly doped region and over the heavily doped region of the silicon layer at a first temperature. The method also includes hydrogenating the heavily doped region of the silicon layer to reduce the dependence of the capacitance between the gate metal and the heavily doped region upon a bias voltage, and forming a via through the first and second dielectric layers above the heavily doped region. The method further includes depositing a conductive layer over the via.

In a further embodiment, a TFT for a liquid crystal display (LCD) having an array of pixels is provided. The TFT includes a silicon layer comprising a plurality of crystals, the plurality of crystals being aligned in the orientation <100> to reduce the dependence of the capacitance between a gate electrode and the heavily doped drain region of the silicon C_{gd} upon a bias voltage. The TFT also includes an insulation layer comprising a first portion over the lightly doped region and a second portion over the non-doped region. The TFT further includes the gate electrode over the second portion of the insulation layer above the non-doped region, a dielectric layer disposed over the gate metal electrode, over the first portion of the insulation layer, such that a via is formed above the heavily doped region. The TFT also includes a conductive layer over the via to connect to the heavily doped region, the bias voltage being applied between the gate electrode and the conductive layer.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

FIG. 1 illustrates a perspective view of a sample tablet computing device.

FIG. 2 illustrates a cross-sectional view of the tablet computing device of FIG. 1.

FIG. 3 shows a simplified diagram illustrating the arrangement of an array of display pixels and the GIP TFT area and demultiplexing TFT area as well as integrated circuits (IC) for a touch panel in an embodiment.

FIG. 4A shows a simplified diagram illustrating configurations of touch panel sub-region or pixels in according with embodiments of the present disclosure.

FIG. 4B shows an enlarged view of the touch panel sub-region of FIG. 4A.

FIG. 5A shows a cross-section view of a TFT stack of an LCD in according with embodiments of the present disclosure.

FIG. 5B shows an enlarged view of the inter layer dielectric (ILD) of FIG. 5A.

FIG. 6 shows capacitance variation versus bias voltage of the TFT in according with embodiments of the present disclosure.

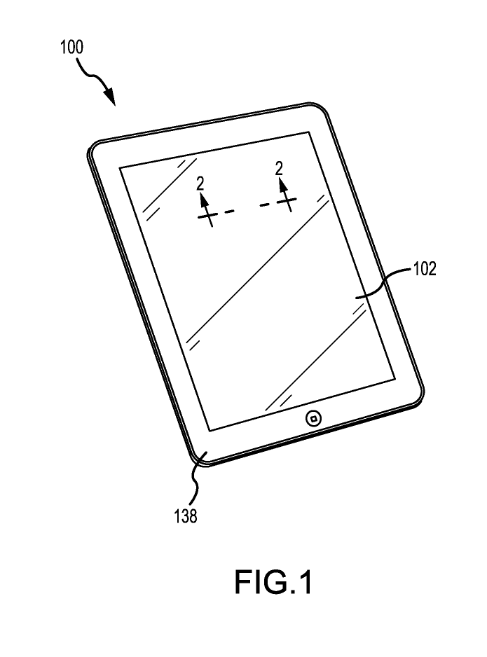

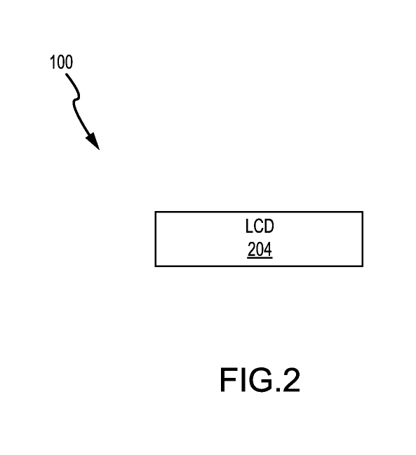

### DETAILED DESCRIPTION

The present disclosure may be understood by reference to the following detailed description, taken in conjunction with the drawings as described below. It is noted that, for purposes of illustrative clarity, certain elements in various drawings may not be drawn to scale.

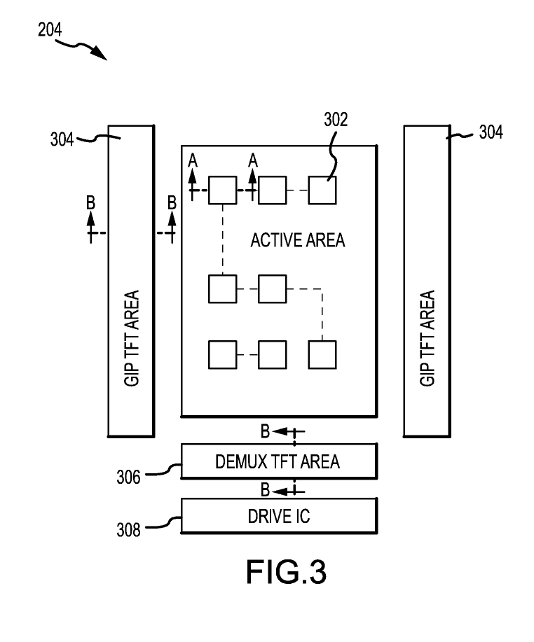

FIG. 3 shows a simplified diagram illustrating the arrangement of an array of pixels and the Gate-Integrated Panel (GIP) TFT area and demultiplexing TFT area as well as integrated circuits for touch panel in an embodiment. As shown, the array of display pixels 302 (also referred to as the “active area”) is surrounded by the GIP TFT area 304 and the demultiplexing TFT area 306. Each display pixel 302 includes a TFT for switching the pixel on and off. The GIP TFT area 302 is used for driving gate lines (not shown) of the display pixels 302, while the demultiplexing TFT area 306 is used for driving data lines (not shown) of the display pixels 302. The integrated circuit 308 typically is positioned nearby the demultiplexing TFT area 306, although this need not be the case.

One method of reducing display noise is by implementing a lower doped region in a portion of the drain of one or more TFTs in the active area 302 (or in the active area itself) than the area outside the active area, such as GIP TFT area 304 and demultiplexing TFT area 306. This method is disclosed in patent application Ser. No. 13/641,826, entitled “Two Doping Regions in Lightly Doped Drain for Thin Film Transistors and Associated Doping Processes,” filed on Aug. 31, 2012, which is incorporated herein by reference.

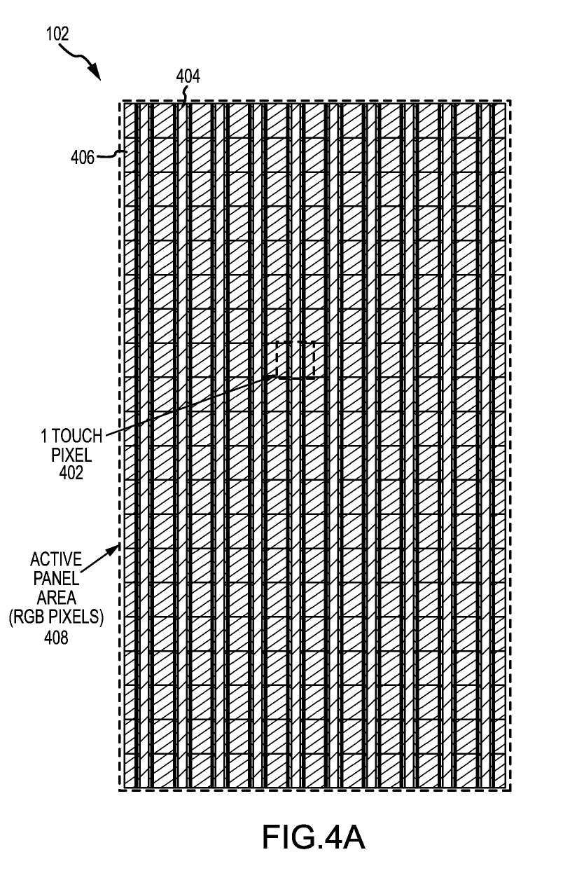

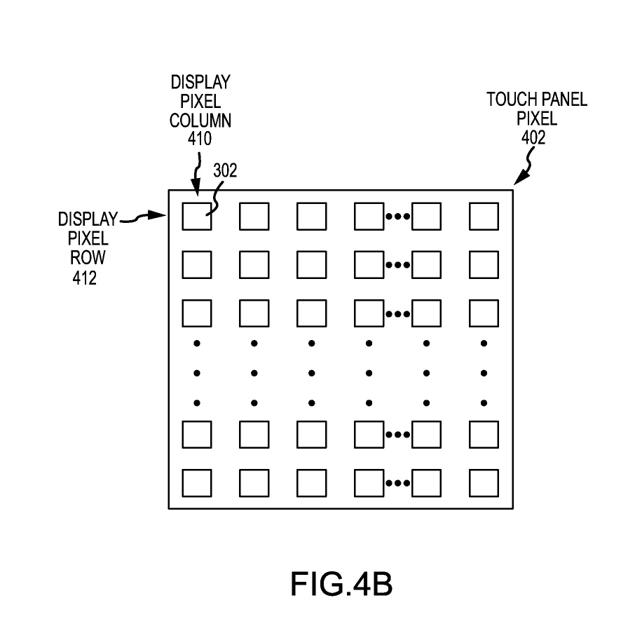

This disclosure provides various embodiments of TFT to reduce display noise that may result in parasitic capacitances on a capacitive touch sensor array, which may reduce the sensitivity of the touch sensor array to an external touch or cause the array to register a phantom touch. FIG. 4A shows a simplified diagram illustrating one sample configuration of touch panel sub-regions or touch panel pixels for the touch panel in according with embodiments of the present disclosure. As shown, touch panel 102 includes a number of touch drive rows 406, and a number of touch sense columns 404 in an active area 408 (surrounded by dash lines) of the LCD 204 and the touch panel 102. In a particular embodiment, the touch panel 102 may include 10 touch sense columns 404 and 20 touch drive rows 406. A touch panel sub-region 402 is defined by the intersection of the touch drive row 406 and the touch sense column 404. Each touch drive row 406 is coupled to an AC source (not shown). Each touch sense column 404 is coupled to a charge amplifier (not shown).

FIG. 4B shows an enlarged view of the touch panel sub-region 402 of FIG. 4A. In the touch panel sub-region 402, there are a number of display pixels 302. As shown, there are a number of display pixel columns 410 in the touch panel sub-region 402, and there are also a number of display pixel rows 412 in touch panel sub-region 402.

Each pixel has a TFT that includes a gate electrode, a source electrode, and a drain electrode. The gate controls turning on and off the TFT. A typical RGB pixel may include three sub-pixels for red, green, and blue colors. In each sub-pixel, there are four major nodes, namely the VCOM, PIXEL, DATA and GATE. The VCOM and GATE nodes are shared among the all three sub-pixels, while the DATA and PIXEL nodes are unique for each sub-pixel. A storage capacitor with a storage capacitance is present between the PIXEL and VCOM nodes for each sub-pixel. The GATE node controls the charging of the storage capacitor. The charge on the storage capacitor controls the orientation of the liquid crystal molecules in a respective pixel, which in turn controls the transmittance of the pixels in the LCD. The GATE node connects to the gate line. In embodiment described below, the DATA node connects to the data line that is connected to the source electrode. The PIXEL node is connected to the drain electrode.

With respect to the touch panel, a touch sensing operation generates a change in capacitance or a change in charge. If there is no touch, there is no change in charge. A charging amplifier amplifies the change in charge and outputs a voltage signal that may be used to determine the location and/or presence of a touch. The touch sensing operation is performed during the blanking interval of the display. In other words, during the touch sensing operation, the display-related TFTs are off.

In the present disclosure, the capacitance between the gate electrode and drain electrode may vary with a voltage applied between the gate electrode and the drain electrode V_{gd} (e.g., a bias voltage). The capacitance C_{gd} depends upon the dielectric properties of the layers in a path between the gate electrode and the drain electrode, for example, gate insulator 504, polysilicon 502 including non-doped region 502A, LDD region 502B, heavily doped region 502C coupled between the gate electrode 506 and the drain electrode 518 or conductive layer 510B. The capacitance variation due to the bias voltage may be reduced by hydrogenation of the heavily doped region of the polycrystalline silicon or polysilicon. Hydrogenation may be achieved by increasing the ratio of hydrogen containing precursors in a precursor mixture, and/or by lowering the temperature during chemical vapor deposition (CVD) of a dielectric layer above the heavily doped region. A portion of this dielectric layer above the heavily doped regions is removed to form vias above the heavily doped regions. A conductive layer is disposed in the vias to connect to the heavily doped region. A portion of the conductive layer by one via forms the drain electrode and another portion of the conductive layer by a neighboring via forms the source electrode.

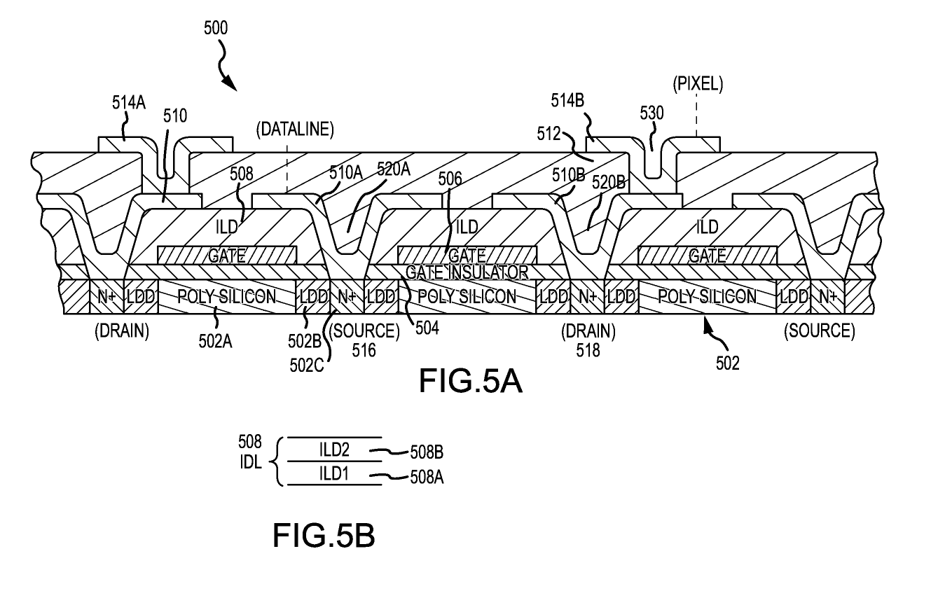

FIG. 5A shows a cross-section view of a TFT stack of an LCD in accordance with embodiments of the present disclosure. The TFT stack 500 includes a silicon layer 502, a gate metal electrode 506 (also called a gate electrode), and a gate insulation layer 504 between the gate metal electrode 506 and the silicon layer 502. The silicon layer 502 may be polycrystalline or polysilicon, as one example. The silicon layer 502 includes a non-doped region 502A under the gate metal electrode 506, a lightly doped drain (LDD) region 502B next to the non-doped region 502A, and a heavily doped region 502C denoted by N+next to the LDD region 502B.

The gate insulator 504 is patterned to expose the heavily doped region 502C. The gate metal is patterned to expose the doped region, including the heavily doped region (N+) and the lightly doped drain (LDD) region.

The TFT stack 500 also includes an inter-layer dielectric (ILD) 508 disposed over the patterned gate electrode 508 and the patterned gate insulation layer 504. The ILD 508 may be deposited by a CVD process. During the deposition of the ILD 508, the heavily doped region of the silicon layer is hydrogenated by hydrogen containing gases in the mixture of the precursors. More details will be provided later on hydrogenation process. The ILD 508 is then patterned to expose the heavily doped region 502C, which is denoted by N+ in FIG. 5A and is part of the silicon layer 502.

The TFT stack 500 further includes a conductive layer 510 disposed over the heavily doped region (N+) 502C and a portion of the ILD 508. Vias 520A, B are formed above the heavily doped region 502C. The conductive layer 510 includes a first portion 510A lining the via 520A, which forms the source electrode 516 and a second portion 510B lining via 520B to forms the drain electrode 518. The conductive layer 510 extends from the vias 520 to cover a top portion of the ILD 508. The heavily doped regions on both sides of the gate electrode 508 connect to the conductive portions 510A (source electrode 516) and 510B (drain electrode 518).

The gate insulation layer 504 may be formed of silicon oxide or silicon nitride. The ILD 508 may also be formed of silicon oxide or silicon nitride. The gate metal 506 may be formed of a metal or metal alloy, for example, molybdenum or molybdenum alloys, such as a molybdenum tungsten alloy (MoW). MoW has better electrical conductivity than ITO. The conductive layer 510 may be formed of metal or metal alloy, such as molybdenum or molybdenum alloys, such as a molybdenum tungsten alloy (MoW), among other suitable materials.

The TFT stack 500 further includes a passivation layer 512 that fills the via 520 over the conductive layer 510. The passivation layer is also referred to a “planarization layer,” and provides a flat surface for forming more layers, such as forming pixel electrodes 514 (e.g., PIXEL node) among others. The passivation layer 512 may be formed of an organic insulator, such as a photoactive compound (PAC). The passivation layer 512 forms via 530, which is horizontally shifted from via 520B, where pixel electrode 514 is disposed and extends to cover a top portion of the passivation layer 512. The conductive layer 510B includes a flat portion on top of the ILD 508 and a portion in via 520B. The pixel electrode 514 is connected to the flat portion of the conductive layer 510B or drain electrode 518.

As shown, the TFT stack 500 includes multiple gate electrodes 506, each for a different TFT. The TFT stack 500 also includes multiple drain electrodes 518, multiple source electrodes 516, multiple pixel electrodes 514 (e.g. 514A-B), multiple vias 520, multiple portions (e.g. 510A-B) of conductive layer 510. Each TFT including a gate electrode, a source electrode, and a drain electrode with a pixel electrode is for controlling one pixel. The first portion 510A of conductive layer 510, connected to one heavily doped region 502C (forming a source electrode 516 of the TFT 500), is coupled to the data line or the DATA node. The second portion 510B of the conductive layer 510, connected to a neighboring heavily doped region 502C (forming a drain electrode 518 of the TFT 500), is coupled to the pixel electrode 514. The pixel electrode 514 may be formed of a transparent indium-tin oxide (ITO), among other suitable materials.

Photoresist is used to assist in forming the predetermined gate insulator pattern 504, gate pattern 506, and predetermined doping regions 502B and 502C as shown in FIG. 5A. Generally, the photoresist film may be made of a photosensitive material; exposure to light (or particular wavelengths of light) may develop the photoresist. The developed photoresist may be insoluble or soluble to a developer, such as a particular chemical. Two distinct types of photoresist may be used, namely a positive photoresist and a negative photoresist. The positive photoresist is soluble to a photoresist developer. That is, the portion of the positive photoresist that is unexposed to light is insoluble to the photoresist developer. The negative resist is a type of photoresist in which the portion of the photoresist that is exposed to light becomes insoluble to the photoresist developer. Further, the unexposed portion of the photoresist is dissolvable by the photoresist developer.

The photoresist is first deposited on a surface, and then light is selectively passed through a patterned mask that may block light in certain areas. The exposed photoresist film is developed through the patterned mask to form the photoresist patterns shown in the figures (or other patterns, as desired). The exposed photoresist film protects the layers underneath during an etching process, such that the portion exposed by the photoresist may be completely removed by the etching process. The etching process may be wet or dry. Portions of underlying layers that are protected by photoresist generally are not removed or otherwise etched. After etching, the insoluble photoresist is removed prior to the next deposition operation. Different masks may be provided to form various films with different patterns. In alternative embodiments, different photoresists may be used.

FIG. 5B shows an enlarged view of the inter layer dielectric (ILD) of FIG. 5A. The ILD 508 may include a first layer 508A and a second layer 508B. The first layer 508A may be formed at a first temperature during a CVD and the second layer 508B may be formed at a second temperature higher than the first temperature during the CVD. In a particular embodiment, the first layer 508A may be 25-50% of the ILD 508.

Chemical vapor deposition (CVD) is a chemical process for fabrication of high purity solid materials. The CVD process may be used in semiconductor manufacturing to produce thin films. In a typical CVD process, a substrate is exposed to one or more volatile precursors in a reaction chamber, which react and/or decompose on the substrate surface to produce the desired deposition. Volatile by-products may also be produced, which are normally removed by gas flow through the reaction chamber. The deposited materials may be in various forms, including mono-crystalline, polycrystalline, amorphous, and epitaxial among others. The materials for CVD include: silicon; silicon oxide (SiO₂); silicon nitride (SiNₓ); silicon-germanium; tungsten; silicon carbide; silicon oxynitride; titanium nitride; and various dielectric materials. The precursors are normally preheated to an elevated temperature. Intrinsic and doped polysilicon may be used i as the active and/or doped layers in thin film transistors (TFT).

The CVD deposition process may include low pressure chemical vapor deposition (LPCVD) and plasma-enhanced chemical vapor deposition (PECVD) processes, among others. These processes may require relatively high temperatures of at least 300° C. A PECVD process utilizes plasma to enhance chemical reaction rates of the precursors. Generally, PECVD processing allows deposition at lower temperatures. The chemical reaction may occur after a plasma of the reacting gases is created. The plasma is generally created by radio frequency alternating current, although a direct current discharge between two electrodes may alternately be employed. The space between the electrodes is filled with the reacting gases.

Silicon dioxide may be deposited using a combination of silicon precursor gases, such as dichlorosilane or silane, and oxygen precursors, such as oxygen and nitrous oxide, typically at pressures from a few millitorr to a few torr. High-density plasma deposition of silicon dioxide from silane and/or oxygen/argon may be used to create a nearly hydrogen-free film with good conformality over complex surfaces. Silicon dioxide may also be deposited from a tetraethoxysilane (TEOS) silicon precursor in an oxygen or oxygen-argon plasma. However, these films may be contaminated with carbon and hydrogen as silanol.

Silicon nitride may be formed from silane and ammonia or nitrogen. Plasma nitrides may contain an amount of hydrogen, which can be bonded to silicon (Si—H) or nitrogen (Si—NH).

Conventionally, a hydrogen plasmas is used for hydrogenation of the silicon, followed by CVD of the ILD. Another common method is to use hydrogen rich silicon nitride deposition first and then deposit silicon dioxide, in which the ILD includes a SiN layer and a SiO₂ layer.

In one embodiment, the temperature for the CVD of the ILD 508 may be lower than 300° C., which may help increase hydrogenation of the heavily doped region 502C of the silicon layer 502. Hydrogenation is a form of chemical reaction between molecular hydrogen (H₂) and another compound or element, usually in the presence of a catalyst. The process is commonly employed to reduce or saturate organic compounds. Most hydrogenations use hydrogen (H₂) containing gases. Hydrogenation typically constitutes the addition of pairs of hydrogen atoms to an element. A hydrogenation may occur to silicon-silicon bonds. During the reaction, a silicon-to-silicon bond may be broken, and hydrogen may be added to bond to silicon. For example, a silicon may have four silicon-to-silicon bonds prior to hydrogenation. After hydrogenation, the silicon may have two silicon-to-silicon bonds and two silicon-to-hydrogen bonds.

Hydrogenation of silicon may result in more stable silicon, and less variation between two states, a positive silicon (S+) and a negative silicon (S−), which may depend upon the bias voltage. This stable silicon may help reduce the variation of capacitance C_{gd} between the gate electrode and the drain electrode (or the pixel electrode) with the bias voltage.

Although the hydrogenation is increased by lowering the temperature for the CVD of the ILD, there may be an adhesion issue between the ILD and the conductive layer 510. Referring to FIG. 5B again, a first ILD 508A may be deposited at a first temperature, such as lower than 300° C., to help hydrogenation and a second ILD 508B may be deposited at a second temperature higher temperature than the first temperature or 300° C., such that better adhesion may be achieved. In a particular embodiment, the second temperature may range from about 320° C. to about 350° C.

Each crystal of the polycrystalline silicon may be orientated in [001] orientation such that the silicon has less variation, which may further help reduce the dependence of the capacitance between the gate electrode and the drain electrode (or pixel electrode) upon the bias voltage.

A laser crystallization technique may be used to crystallize an amorphous silicon (a-Si) material on a substrate without melting or damaging the substrate. The substrate may include a glass substrate and a plastic substrate that may be used for digital displays with flexible screens.

The laser provides short, high-intensity ultraviolet laser pulses to heat the deposited a-Si material to above the melting point of silicon, without melting the entire substrate. The molten silicon will then crystallize as it cools. Silicon generally crystallizes in a diamond cubic crystal structure. Coordinates in square brackets, such as [100] denote a direction vector in real space. In the cubic crystal system, <100> includes [100], [010], [001] or the negative of any of those directions. By controlling cooling time from melting state and laser power, the desired crystal orientation may be achieved. For example, most small crystals of the polycrystalline silicon may be oriented in the same orientation such as <100>.

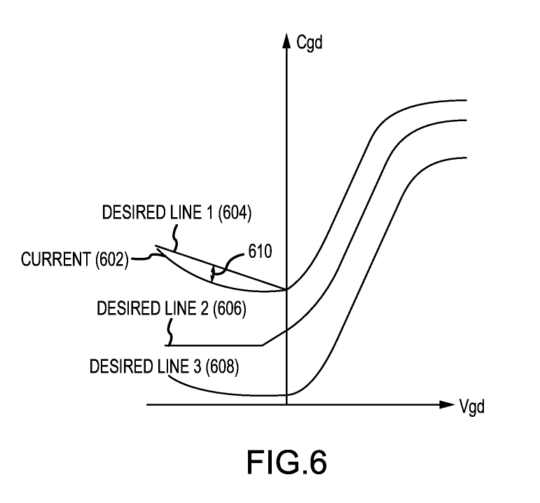

An AC source may be used to measure capacitor variation as a functional of bias voltage for a TFT. FIG. 6 shows capacitance variation versus bias voltage in according with embodiments of the present disclosure. When display images change from a dark color to a light color, for example, a black color to a white color, the C_{gd} dependence upon V_{gd} may vary. For example, C_{gd} has a curved dependence upon the V_{gd} as current curve 602 shows. The curve 602 corresponds to a black image on the display. Line 604 shows a linear relationship between C_{gd} and V_{gd}, which corresponds to a white image on the display. A delta C_{gd} between curve 602 for the black image and line 604 for the white image, as the arrow 610 shows, or a delta C_{gate/pixel} is a dominant parameter for the display noises. It is desirable to reduce the delta C_{gd}.

The linear relationship between C_{gd} and V_{gd} and/or lower C_{gd} may result in a smaller delta in C_{gd} due to display image changes, and thus lower display noises. For example, line 604 is linear, which may be desirable insofar as the capacitance varies directly with bias voltage, instead of increasing in a more than linear fashion. Line 606 is also desirable because it has a lower intercept with the vertical axis (e.g., C_{gd}) than line 604. When the C_{gd} value is low enough, the variation in C_{gd} is negligible. Although the slope of line 604 is negative while line 606 has almost zero slope, the delta C_{gd} is not affected by the slope, as long as lines 604 and 606 are substantially linear. Furthermore, line 608 is desirable because it has a very low value compared to Lines 606 and 604. Although line 608 is curved, but the curvature does not affect the delta C_{gd}, because C_{gd} is very small.

Low dependence of display noise with respect to V_{gd} is achieved when low dependence of C_{gd} upon V_{gd} is obtained. Reliability tests have correlated the sensitivity of the display noise to V_{gd}. Generally, when C_{gd} is not sensitive to V_{gd}, the display noise is invariant, which means that the display noise is not sensitive to V_{gd}. For example, the display noise may be measured before and after a reliability test, such as a heat soak, to determine if the display noise has change or shift or not. If there is no change or shift in the display noise after heat soak, the display noise is not sensitive to V_{gd}. Although hydrogenation also helps reduce the variation of the capacitance C_{gs} between the gate electrode and the source electrode, like the effect on the variation of capacitance C_{gd}, the C_{gs} variation versus voltage V_{gs} between the gate electrode and the source electrode does not affect the display noises as the C_{gd} variation does.

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A TFT stack for a liquid crystal display, the stack comprising:
a silicon layer comprising a heavily doped region, a non-doped region, and a lightly doped region between the heavily doped region and the non-doped region, the heavily doped region being hydrogenated;
an insulation layer comprising a first portion formed over the lightly doped region and a second portion disposed over the non-doped region;
a gate metal electrode layer formed over the second portion of the non-doped region;
a first dielectric layer disposed over the gate metal electrode and over the first portion of the insulation layer, the first dielectric layer being formed through a chemical vapor deposition (CVD) process at a first temperature, wherein a via is formed above the heavily doped region; and
a conductive layer over the via to contact the heavily doped region, wherein the heavily doped region is hydrogenated to reduce the dependence of the capacitance between the gate metal electrode and the conductive layer C_{gd} upon a bias voltage being applied between the gate metal electrode and the conductive layer.

2. The TFT stack of claim 1, wherein the silicon comprises a plurality of crystals, the plurality of crystals being aligned in orientation <100> to reduce the dependence of the capacitance C_{gd} upon the bias voltage.

3. The TFT stack of claim 1, further comprising a second dielectric layer disposed over the first dielectric layer, the second dielectric layer being formed through the CVD process at a second temperature higher than the first temperature.

4. The TFT stack of claim 3, wherein the first and second dielectric layers comprise silicon oxide or silicon nitride.

5. The TFT stack of claim 1, wherein the conductive layer comprises indium-tin oxide.

6. A method for fabricating a TFT stack, the method comprising:
depositing a silicon layer on a substrate, the silicon layer comprising a heavily doped region, a non-doped region, and a lightly doped region between the heavily doped region and the non-doped region;
forming an insulation layer having a first portion over the lightly doped region and a second portion over the non-doped region;
forming a gate metal electrode over the second portion of the insulation layer above the non-doped region of the silicon layer;
depositing a first dielectric layer over the gate metal electrode by using a mixture of precursors comprising hydrogen containing precursors during a chemical vapor deposition (CVD), over the first portion of the insulator layer above the lightly doped region, and over the heavily doped region of the silicon layer at a first temperature;
hydrogenating the heavily doped region of the silicon layer to reduce the dependence of the capacitance between the gate metal and the heavily doped region upon a bias voltage; and
forming a via through the first and second dielectric layers above the heavily doped region; and
depositing a conductive layer over the via.

7. The method of claim 6, further comprising crystallizing a plurality of crystals in the silicon layer to align the plurality of crystals in orientation <100>.

8. The method of claim 6, wherein the precursors is selected from a group consisting of silane (SiH₄), ammonia (NH₃), nitrous oxide (N₂O), hydrogen (H₂), and nitrogen (N₂).

9. The method of claim 6, wherein the hydrogen containing precursors is selected from a group consisting of SiH₄, NH₃, and H₂.

10. The method of claim 6, wherein the first temperature is about 300° C.

11. The method of claim 6, wherein the second temperature ranges from about 320° C. to 350° C.

12. The method of claim 6, wherein the second dielectric layer is thicker than the first dielectric layer.

13. The method of claim 6, wherein the first and second dielectric layers comprise silicon oxide or silicon nitride.

14. A TFT for a liquid crystal display (LCD) having an array of pixels, the TFT comprising:
a silicon layer comprising a plurality of crystals, the plurality of crystals being aligned in the orientation <100> to reduce the dependence of the capacitance between a gate electrode and the heavily doped drain region of the silicon C_{gd} upon a bias voltage;
an insulation layer comprising a first portion over the lightly doped region and a second portion over the non-doped region;
the gate electrode over the second portion of the insulation layer above the non-doped region;
a dielectric layer disposed over the gate metal electrode and over the first portion of the insulation layer, such that a via is formed above the heavily doped region; and
a conductive layer over the via to connect to the heavily doped region, the bias voltage being applied between the gate electrode and the conductive layer.

15. The TFT of claim 14, wherein the dielectric layer comprises:
a first dielectric layer disposed over the gate metal electrode, the first dielectric layer being formed through a chemical vapor deposition (CVD) process at a first temperature; and
a second dielectric layer disposed over the first dielectric layer, the second dielectric layer being formed through the CVD process at a second temperature higher than the first temperature.

16. The TFT of claim 15, wherein the CVD comprises a mixture of precursors comprising hydrogen containing precursors.

17. The TFT of claim 15, wherein the first temperature is about 300° C.

18. The TFT of claim 15, further comprising depositing a second dielectric layer over the first dielectric layer at a second temperature higher than the first temperature, wherein the second temperature ranges from about 320° C. to 350°l C.

19. The TFT of claim 18, wherein the second dielectric layer is thicker than the first dielectric layer.

20. The TFT of claim 18, wherein the first and second dielectric layers comprise silicon oxide or silicon nitride.

21. The TFT of claim 15, wherein the conductive layer comprises indium-tin oxide.
